(19) United States
(12) Patent Application Publication
(10) Pub. No.: US 2009/0278243 A1
(43) Pub. Date: Nov. 12, 2009

(54) STACKED TYPE CHIP PACKAGE STRUCTURE AND METHOD FOR FABRICATING THE SAME

(75) Inventors: Yao-Kai Chuang, Kaohsiung City (TW); Chih-Ming Chung, Kaohsiung County (TW); Chien Liu, Kaohsiung City (TW); Chao-Cheng Liu, Kaohsiung County (TW)

Correspondence Address: J C PATENTS, 4 VENTURE, SUITE 250, IRVINE, CA, 92618, US

(73) Assignee: Advanced Semiconductor Engineering, Inc., Kaohsiung (TW)

(21) Appl. No.: 12/429,476

(22) Filed: Apr. 24, 2009

(30) Foreign Application Priority Data
May 12, 2008 (TW) 97117466

(51) Int. Cl. H01L 23/52; H01L 21/98

(52) U.S. Cl. 257/676; 438/107; 257/E23.141; 257/E21.705

(57) ABSTRACT

A stacked type chip package structure including a chip carrier, a first chip, a second chip, a third chip, and an insulating material is provided. The chip carrier includes two die pads and a plurality of leads surrounding the die pads. The first chip and the second chip are disposed on the die pads respectively, and are electrically connected to the leads by wire bonding. The third chip traverses the first chip and the second chip, and is electrically connected to the first chip and the second chip respectively. The insulating material is disposed on the chip carrier for encapsulating the first chip, the second chip and the third chip, and fills among the die pads and the leads.

### CROSS-REFERENCE TO RELATED APPLICATION

This application claims the priority benefit of Taiwan application serial no. 97117466, filed on May 12, 2008. The entirety of the above-mentioned patent application is hereby incorporated by reference herein and made a part of specification.

### BACKGROUND OF THE INVENTION

1. Field of the Invention

The present invention relates to a chip package structure and a method for fabricating the same, and particularly relates to a stacked type chip package structure and a method for fabricating the same.

2. Description of Related Art

In semiconductor-related industry, the production of integrated circuits (IC) is mainly divided into three stages, which includes IC design, IC process and IC package.

During the fabrication of an IC, a chip is manufactured by the steps of wafer fabrication, IC formation, wafer sawing, and so forth. A wafer has an active surface, which generally refers to the surface including active devices. After the IC inside the wafer is completed, a plurality of bonding pads is further disposed on the active surface of the wafer, such that the chip formed by wafer sawing can be externally electrically connected to a carrier through the bonding pads. The carrier is, for example, a lead frame or a package substrate. The chip can be connected to the carrier by wire bonding or by flip chip bonding, such that the bonding pads on the chip can be electrically connected to contacts of the carrier to form a chip package structure.

FIGS. 1A-1E are schematic cross-sectional views illustrating a process flow for fabricating a semiconductor device disclosed in Japan Patent publication No. 2005-317998. First, referring to FIG. 1A, a copper foil 21 is provided. The copper foil 21 has a top surface and a bottom surface on which a first patterned metal layer 22 and a second patterned metal layer 23 are respectively formed to be used as electrical contacts. Referring to FIG. 1B, an etching impedance layer 24 is formed on the bottom surface of the copper foil 21. Next, the first patterned metal layer 22 is used as an etching mask to perform a half-etching process on the top surface of the copper foil 21 so as to form a plurality of recesses R on the top surface. Thereafter, referring to FIG. 1C, an adhesion layer 20 is used to attach a semiconductor device 11 to one of the recesses R which are used as die pads. A plurality of conductive wires 16 is formed between the semiconductor device 11 and a wire bonding section 12 of the copper foil 21. Then, referring to FIG. 1D, a second insulating material 18 is formed on the top surface of the copper foil 21 to encapsulate the semiconductor device 11, the conductive wires 16, and the top surface of the copper foil 21. Finally, referring to FIG. 1E, the second patterned metal layer 23 is used as the etching mask to perform a back-etching process on the bottom surface of the copper foil 21 so as to form a chip package structure 10 having area array leads.

A new type of QFN package is fabricated by the aforesaid method which uses the whole copper foil to etch and form the die pads and the leads. The QFN package has the advantage of increasing the number of the leads, so as to achieve the miniaturization and high density of the package fabricated by the above processes. However, this type of QFN package is mainly applied in the fabrication of a single-chip package, which does not meet the current trend of multi-chip module packages. Hence, how to improve the fabrication processes of the new QFN package structure for integrating more chips in a stacked type chip package structure has become a great challenge.

### SUMMARY OF THE INVENTION

The present invention provides a stacked type chip package structure and a method for fabricating the same, which mainly apply the concept of stacking chips in the new QFN package, so as to improve the package density of the whole chip package structure.

The present invention provides a stacked type chip package structure, which comprises a chip carrier, a first chip, a second chip, a third chip, and an insulating material. The chip carrier has a first surface and a second surface opposite to the first surface, and the chip carrier comprises two die pads and a plurality of leads surrounding the die pads. The first chip is disposed on one of the die pads. The second chip is disposed on the other die pad. Herein, the first chip and the second ship are electrically connected to the leads through a plurality of first conductive wires. The third chip traverses the first chip and the second chip, and is electrically connected to the first chip and the second chip. The insulating material is disposed on the chip carrier to encapsulate the first chip, the second chip, and the third chip, and fill among the die pads and the leads.

In an embodiment of the present invention, the third chip is electrically connected to the first chip and the second chip through a plurality of second conductive wires.

In an embodiment of the present invention, the stacked type chip package structure further comprises a plurality of bumps disposed between the third chip and the first chip and between the third chip and the second chip, so as to electrically connect the third chip to the first chip and the second chip.

In an embodiment of the present invention, the chip carrier further comprises a nickel/silver or nickel/gold layer disposed on the first surface of the chip carrier.

In an embodiment of the present invention, the chip carrier further comprises a nickel/silver or nickel/gold layer disposed on the second surface of the chip carrier.

In an embodiment of the present invention, the third chip is further electrically connected to the leads through a plurality of third conductive wires.

The present invention further provides a method for fabricating a stacked type chip package structure, which comprises the following. First, a metal plate, a first chip, a second chip, and a third chip are provided. The metal plate has a first surface, a second surface, a first patterned metal layer on the first surface and a second patterned metal layer on the second surface, and the third chip has a surface comprising a plurality of bumps. Next, the first patterned metal layer is used as an etching mask to perform a half-etching process on the first surface of the metal plate, so as to form a plurality of first recesses on the first surface. Herein, the first recesses define two die pads and a plurality of leads surrounding the two die pads in the metal plate. Then, the first chip and the second chip are respectively disposed on the two die pads. The first chip is electrically connected to a portion of the leads and the second chip is electrically connected to other leads through wire bonding. Thereafter, the third chip is disposed to traverse the first chip and the second chip. A flip chip bonding technique is used to electrically connect the third chip to the first chip and the second chip through the bumps. Following that, an insulating material is formed on the first surface of the metal plate, wherein the insulating material encapsulates the first chip, the second chip, and the third chip, and fills the first recesses. Finally, the second patterned metal layer is used as an etching mask to perform a back-etching process on the second surface of the metal plate, so as to form a plurality of second recesses on the second surface. Herein, the second recesses respectively correspond to the first recesses, and expose the insulating material filling the first recesses, so as to electrically insulate the two die pads and the leads from one another.

In an embodiment of the present invention, the material of the metal plate is copper.

In an embodiment of the present invention, the first patterned metal layer is a nickel/silver or nickel/gold layer.

In an embodiment of the present invention, the second patterned metal layer is a nickel/silver or nickel/gold layer.

In an embodiment of the present invention, the first chip is attached to the die pad through an adhesion layer.

In an embodiment of the present invention, the second chip is attached to the die pad through an adhesion layer.

The present invention further provides a method for fabricating a stacked type chip package structure, which comprises the following. First, a metal plate, a first chip, a second chip, and a third chip are provided. Herein, the metal plate comprises a first surface, a second surface, a first patterned metal layer, and a second patterned metal layer. The first patterned metal layer and the second patterned metal layer are respectively disposed on the first surface and the second surface. Further, the metal plate has a plurality of first recesses formed on the first surface for defining two die pads and a plurality of leads surrounding the two die pads in the metal plate, and the third chip has a surface comprising a plurality of bumps. Then, the first chip and the second chip are disposed on the two die pads respectively. Next, the first chip is electrically connected to a portion of the leads and the second chip is electrically connected to other leads through wire bonding. Thereafter, the third chip is disposed to traverse the first chip and the second chip, and the third chip is electrically connected to the first chip and the second chip. Following that, an insulating material is formed on the first surface of the metal plate, wherein the insulating material encapsulates the first chip, the second chip, and the third chip, and fills the first recesses. Finally, the second patterned metal layer is used as an etching mask to perform a back-etching process on the second surface of the metal plate, so as to form a plurality of second recesses on the second surface. Herein, the second recesses respectively correspond to the first recesses, and expose the insulating material filling the first recesses to electrically insulate the die pads and the leads from one another.

In an embodiment of the present invention, the material of the metal plate is copper.

In an embodiment of the present invention, the first chip is attached to the die pad through an adhesion layer.

In an embodiment of the present invention, the second chip is attached to the die pad through an adhesion layer.

In an embodiment of the present invention, the first patterned metal layer is a nickel/silver or nickel/gold layer.

In an embodiment of the present invention, the second patterned metal layer is a nickel/silver or nickel/gold layer.

The stacked type chip package structure according to the present invention mainly adopts wire bonding to attach the two chips onto the die pads of the chip carrier, so as to electrically connect the chips to the leads. Thereafter, another chip is stacked on the two chips through flip chip bonding to complete fabricating the new QFN type of stacked type chip package structure. The present invention provides the aforesaid new fabricating method, which applies the concept of stacked type chip package in the new QFN type package structure, for achieving the miniaturization and high density of the package structure.

To make the above features and advantages of the present invention more comprehensible, several embodiments accompanied with figures are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1E ate schematic cross-sectional views illustrating a process flow for fabricating a semiconductor device disclosed in Japan Patent publication No. 2005-317998.

FIGS. 2A-2G are schematic cross-sectional views illustrating a process flow for fabricating a stacked type chip package structure according to an embodiment of the present invention.

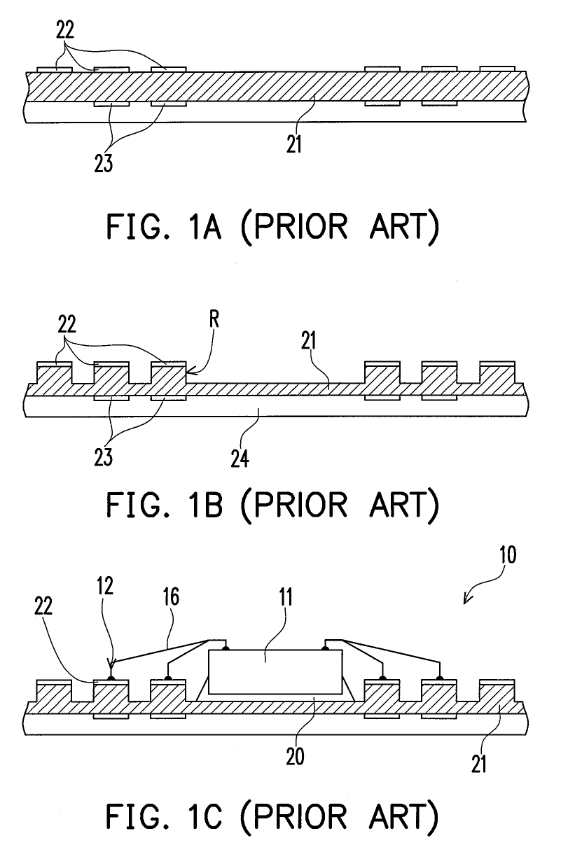

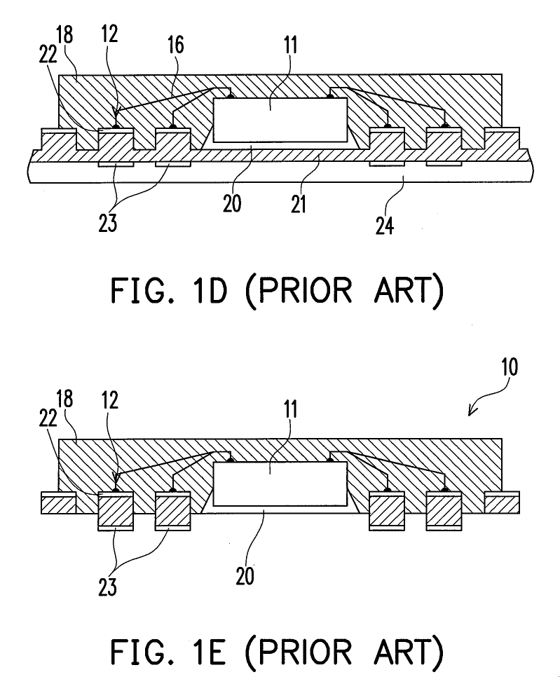

### DESCRIPTION OF EMBODIMENTS

The present invention provides a method for fabricating a stacked type chip package structure, which is applicable in integrating different types of chips, such as common digital chips, analogue chips, memory chips, and so forth. To cover the above variations, different types of chips are indicated as a first chip, a second chip, and a third chip in the following descriptions.

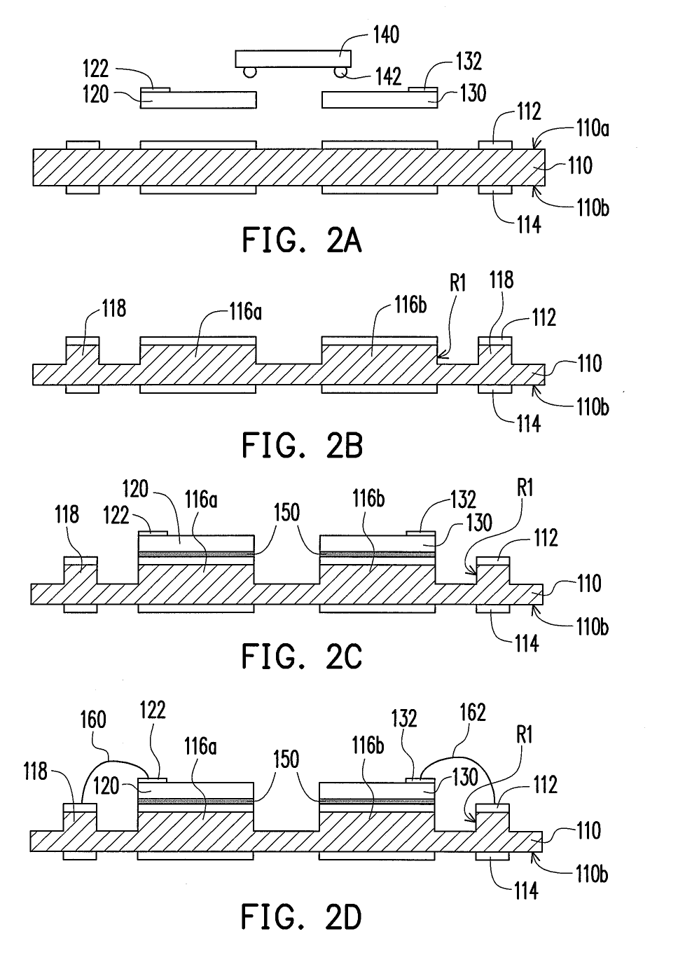

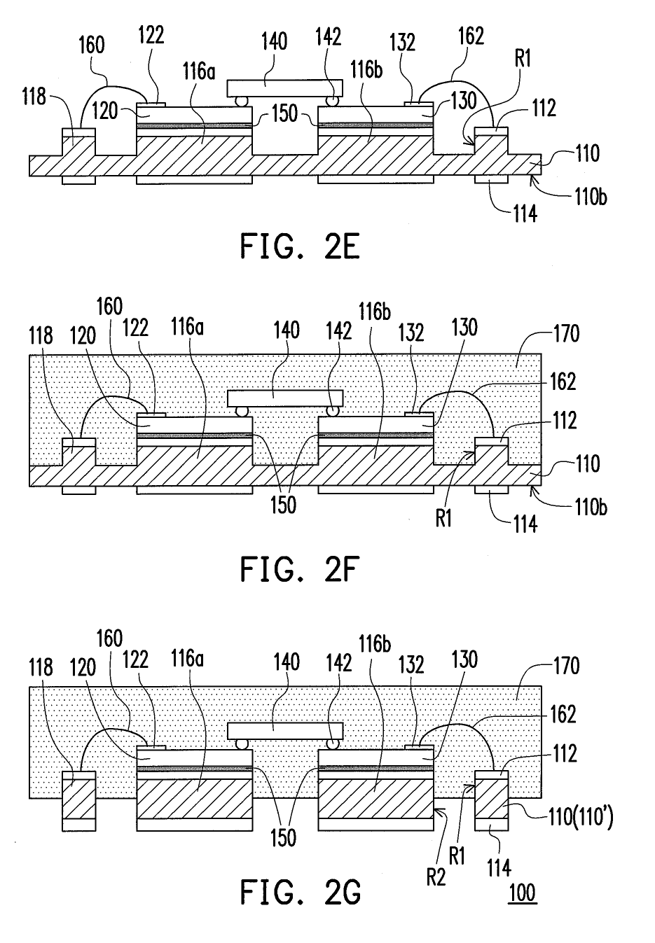

FIGS. 2A-2G are schematic cross-sectional views illustrating a process flow for fabricating a stacked type chip package structure according to an embodiment of the present invention. A new QFN package is taken as an example in this embodiment. First, referring to FIG. 2A, a metal plate 110, a first chip 120, a second chip 130, and a third chip 140 are provided. The metal plate 110 comprises a first surface 110a and a second surface 110b opposite to the first surface 110a. A first patterned metal layer 112 and a second patterned metal layer 114 are respectively formed on the first surface 110a and the second surface 110b. In an embodiment of the present invention, the material of the metal plate 110 is copper. The first patterned metal layer 112 and the second patterned metal layer 114 may be nickel/silver or nickel/gold layers formed by electroplating. The first patterned metal layer 112 and the second patterned metal layer 114 are also adapted for preventing the metal plate 110 from being oxidized. In addition, an active surface of the first chip 120 comprises at least a chip pad 122, an active surface of the second chip 130 comprises at least a chip pad 132, and an active surface of the third chip 140 comprises a plurality of bumps 142.

Next, referring to FIG. 2B, the first patterned metal layer 112 is used as an etching mask to perform a half-etching process on the first surface 110a of the metal plate 110, so as to form a plurality of first recesses R1 on the first surface 110a. The first recesses R1 define two die pads 116a and 116b and a plurality of leads 118 surrounding the die pads 116a and 116b in the metal-plate 110.

Then, referring to FIG. 2C, the first chip 120 and the second chip 130 are respectively disposed on the two die pads 116a and 116b. In this embodiment, an adhesion layer 150 is respectively formed on the die pads 116a and 116b first, and the first chip 120 and the second chip 130 are respectively attached to the die pads 116a and 116b through the adhesion layer 150.

Thereafter, referring to FIG. 2D, the first chip 120 is electrically connected to a portion of the leads 118 and the second chip 130 is electrically connected to other leads 118 through wire bonding. In this embodiment, the wire bonding is used to form a plurality of first conductive wires 160 between the chip pads 122 of the first chip 120 and the leads 118 to electrically connect the first chip 120 to a portion of the leads 118. Similarly, the wire bonding is also used to form a plurality of second conductive wires 162 between the chip pads 132 of the second chip 130 and other leads 118 to electrically connect the second chip 130 to other leads 118.

Then, referring to FIG. 2E, the third chip 140 is disposed to traverse the first chip 120 and the second chip 130. A flip chip bonding technique is used to electrically connect the third chip 140 to the first chip 120 and the second chip 130 through the bumps 142 on the active surface of the third chip 140. In this embodiment, the third chip 140 is electrically connected to the first chip 120 and the second chip 130 through the flip chip bonding technique. However, the third chip 140 may also be electrically connected to the first chip 120 and the second chip 130 through the wire bonding, but the present invention is not limited thereto. In addition, the third chip 140 may also be electrically connected to the leads 118 through a plurality of third conductive wires (not shown) formed by the wire bonding.

Next, referring to FIG. 2F, an insulating material 170 (i.e. compound) is formed on the first surface 110a of the metal plate 110. The insulating material 170 encapsulates the first chip 120, the second chip 130, the third chip 140, the first conductive wires 160, and the second conductive wires 162, and fills the first recesses R1, so as to protect the die pads 116a and 116b, the leads 118, the first chip 120, the second chip 130, the third chip 140, the first conductive wires 160, and the second conductive wires 162 as shown in FIG. 2F from being damaged or contaminated. Finally, referring to FIG. 2G, the second patterned metal layer 114 is used as an etching mask to perform a back-etching process on the second surface 110b of the metal plate 110, so as to form a plurality of second recesses R2 on the second surface 110b. The second recesses R2 respectively correspond to the first recesses R1, and expose the insulating material 170 filling the first recesses R1, so as to electrically insulate the die pads 116a and 116b and the leads 118 from one another. The metal plate 110 can be used as a chip carrier 110′. Thereby, a stacked type chip package structure 100, which is formed by stacking a flip chip on two wire bonding chips, is completed.

In the above embodiments, the whole metal layer of copper is used to etch and form the die pads and the leads of the chip carrier. The process of stacking chips is then performed to complete the fabrication of the stacked type chip package structure 100. However, the first patterned metal layer 112 and the second patterned metal layer 114 may also be respectively formed on the first surface 110a and the second surface 110b of the metal plate 110 first. Then, the first recesses R1 are directly formed on the first surface 110a of the metal plate 110 through a punch process. Following that, the processes as shown in FIGS. 2C-2G are performed to complete the fabrication of a stacked type chip package structure 100′.

The above embodiments illustrate the stacking of two layers of chips as an example. However, the concept according to the present invention is also applicable in stacking multi-layers of chips. The present invention is not intended to limit the number of the layers of chips.

In summary, the present invention utilizes the half-etching process or punch process to form the first recesses on the metal plate, and thereby defines two die pads and the leads. Thereafter, two chips are respectively disposed on the die pads, and electrically connected to the leads through wire bonding. Then, another chip is stacked on the two chips through flip chip bonding, so as to complete fabricating the new QFN type of stacked type chip package structure. The present invention provides the aforesaid new fabricating method, which applies the concept of stacked type chip package in the new QFN type package structure, for achieving the miniaturization and high density of the package structure.

Although the present invention has been disclosed by the above embodiments, they are not intended to limit the present invention. Anybody with ordinary knowledge in the art may make some modifications and alterations without departing from the spirit and scope of the present invention. Therefore, the protection range of the present invention falls in the appended claims.

What is claimed is:

1. A stacked type chip package structure, comprising:
a chip carrier, having a first surface and a second surface opposite to the first surface, and the chip carrier comprising two die pads and a plurality of leads surrounding the die pads;
a first chip, disposed on one of the die pads;
a second chip, disposed on the other die pad, wherein the first chip and the second chip are electrically connected to the leads through a plurality of first conductive wires;
a third chip, traversing the first chip and the second chip, and electrically connected to the first chip and the second chip; and
an insulating material, disposed on the chip carrier to encapsulate the first chip, the second chip, and the third chip, and fill among the die pads and the leads.

2. The stacked type chip package structure as claimed in claim 1, wherein the third chip is electrically connected to the first chip and the second chip through a plurality of second conductive wires.

3. The stacked type chip package structure as claimed in claim 1, further comprising a plurality of bumps disposed between the third chip and the first chip and between the third chip and the second chip so as to electrically connect the third chip to the first chip and the second chip through the bumps.

4. The stacked type chip package structure as claimed in claim 1, wherein the chip carrier further comprises a nickel/silver or nickel/gold layer disposed on the first surface of the chip carrier.

5. The stacked type chip package structure as claimed in claim 1, wherein the chip carrier further comprises a nickel/silver or nickel/gold layer disposed on the second surface of the chip carrier.

6. The stacked type chip package structure as claimed in claim 1, wherein the third chip is further electrically connected to the leads through a plurality of third conductive wires.

7. A method for fabricating a stacked type chip package structure, comprising:
providing a metal plate, a first chip, a second chip, and a third chip, wherein the metal plate has a first surface, a second surface, a first patterned metal layer on the first surface and a second patterned metal layer on the second surface, and the third chip comprising a plurality of bumps on a surface thereof;
performing a half-etching process on the first surface of the metal plate by using the first patterned metal layer as an etching mask, so as to form a plurality of first recesses on the first surface of the metal plate, wherein the first recesses define two die pads and a plurality of leads surrounding the die pads in the metal plate;
disposing the first chip and the second chip on the two die pads respectively;
electrically connecting the first chip to a portion of the leads and electrically connecting the second chip to other leads through wire bonding;
disposing the third chip to traverse the first chip and the second chip, and electrically connecting the third chip to the first chip and the second chip;
forming an insulating material on the first surface of the metal plate, wherein the insulating material encapsulates the first chip, the second chip, and the third chip, and fills the first recesses; and
performing a back-etching process on the second surface of the metal plate by using the second patterned metal layer as an etching mask, so as to form a plurality of second recesses on the second surface of the metal plate, wherein the second recesses respectively correspond to the first recesses and expose the insulating material filling the first recesses to electrically insulate the die pads and the leads from one another.

8. The method as claimed in claim 7, wherein the material of the metal plate is copper.

9. The method as claimed in claim 7, wherein the first patterned metal layer is a nickel/silver or nickel/gold layer.

10. The method as claimed in claim 7, wherein the second patterned metal layer is a nickel/silver or nickel/gold layer.

11. The method as claimed in claim 7, wherein the first chip is attached to the die pad through an adhesion layer.

12. The method as claimed in claim 7, wherein the second chip is attached to the die pad through an adhesion layer.

13. A method for fabricating a stacked type chip package structure, comprising:
providing a metal plate, a first chip, a second chip, and a third chip, wherein the metal plate comprises a first surface, a second surface, a first patterned metal layer, and a second patterned metal layer, the first patterned metal layer and the second patterned metal layer are respectively disposed on the first surface and the second surface, the metal plate further comprises a plurality of first recesses formed on the first surface for defining two die pads and a plurality of leads surrounding the two die pads in the metal plate, and the third chip has a surface comprising a plurality of bumps;
disposing the first chip and the second chip on the two die pads respectively;
electrically connecting the first chip to a portion of the leads and electrically connecting the second chip to other leads through wire bonding;
disposing the third chip to traverse the first chip and the second chip, and electrically connecting the third chip to the first chip and the second chip;
forming an insulating material on the first surface of the metal plate, wherein the insulating material encapsulates the first chip, the second chip, and the third chip, and fills the first recesses; and
using the second patterned metal layer as an etching mask to perform a back-etching process on the second surface of the metal plate, so as to form a plurality of second recesses on the second surface of the metal plate, wherein the second recesses respectively correspond to the first recesses and expose the insulating material filling the first recesses, so as to electrically insulate the die pads and the leads from one another.

14. The method as claimed in claim 13, wherein the material of the metal plate is copper.

15. The method as claimed in claim 13, wherein the first recesses on the metal plate are formed by a punch process.

16. The method as claimed in claim 13, wherein the first chip is attached to the die pad through an adhesion layer.

17. The method as claimed in claim 13, wherein the second chip is attached to the die pad through an adhesion layer.

18. The method as claimed in claim 13, wherein the first patterned metal layer is a nickel/silver or nickel/gold layer.

19. The method as claimed in claim 13, wherein the second patterned metal layer is a nickel/silver or nickel/gold layer.
